(19) United States
(12) Patent Application Publication
(10) Pub. No.: US 2022/0260324 A1
(43) Pub. Date: Aug. 18, 2022

(54) APPARATUS AND COMPOSITION FOR COOLING ITEMS WITH A CONTAINED PHASE CHANGE MATERIAL

(71) Applicant: Hercules Manufacturing Co., Henderson, KY (US)

(72) Inventors: Staffan Akerman, Evansville, IN (US); Jeffrey A. Caddick, Evansville, IN (US)

(73) Assignee: Hercules Manufacturing Co., Henderson, KY (US)

(21) Appl. No.: 17/176,026

(22) Filed: Feb. 15, 2021

(51) Int. Cl. F28D 17/00; C09K 5/06; C09K 5/04; H01L 23/427

(52) U.S. Cl. CPC F28D 17/00; C09K 5/063; F25C 2400/10; H01L 23/427; C09K 5/04

(57) ABSTRACT

A heat sink cooling apparatus of the present invention includes a thickened Phase Change Material (PCM) and an aluminum profile container for superior cold storage, heat transfer and efficiency of defrost. The PCM is a composition including a brine solution and a thickening agent resulting in increased holdover capacity in a no-leak, safe food grade PCM, and a tubular aluminum profile manufactured with a highly conductive aluminum alloy, which can be triangular, with optional internal and/or external fin-tube configurations maximizing surface area for heat transfer. The heat sink cooling apparatus is capable of removing heat from (but not limited to) a transport cargo area (truck body) through the processes of conductive and convection heat transfer via the aluminum profile filled with a PCM, either in a passive form of cooling via free convection (hanging mount) or in a forced air plenum chamber.

### BACKGROUND OF THE INVENTION

### 1. Field of the Invention

The present invention relates to apparatuses and compositions used to cool an interior volume such as, but not limited to, a truck configured to keep items therein cool. More particularly, the present invention relates to the combination of structural materials and configurations with cooling compositions to provide effective heat exchange for a heat sink cooling apparatus. Still more particularly, the present invention relates to the inclusion of a cooling composition that is a phase changing material composition in a heat exchanger structure configured to improve heat transfer between the cooling composition and the item or items to be cooled.

### 2. Description of the Prior Art

A heat sink cooling apparatus is a key component in a refrigeration system, for use in refrigerated and frozen food transport and cold storage with the heat sink cooling apparatus configured in a hanging (ceiling or wall) mount or a plenum chamber (blower unit) application. Containers primarily in the form of beams and plates are a means of refrigerating interior volumes such as, for example, truck bodies. The container is made of a thermally conductive material. A Phase Change Material (PCM) is contained within these containers. The PCM is of the type known to those skilled in the art and may include, but not be limited to, water containing salt, which has a lower freezing temperature than water.

The PCM is conditioned to a temperature that enables the absorption of heat that exists within the interior volume, such as heat from the interior of a truck body. The latent heat of the PCM provides the container with a high heat absorption capacity. Mechanical refrigeration is generally used to freeze the PCM to a temperature that is below the transition point, generally from a liquid to a solid but it may also be from a gas to a liquid. For this purpose, internal refrigerant tubing is placed within the PCM inside the container. The refrigerant tubing is used to remove heat from and freeze the PCM. The structural components of the PCM refrigeration apparatuses that have been used tend to be made of flat steel, which provides poor thermal conductivity and adds substantial weight to the container within which they are deployed.

PCM compositions can undergo repeated freezing/thawing and defrost/freezing cycles. The thermal storage effectiveness of the PCM composition is generally characterized by the latent heat storage capacity of the composition. Latent heat is energy released or absorbed, by a body of a thermodynamic system, during a constant-temperature process—usually a first-order phase transition. Latent heat can be understood as energy in a hidden form which is supplied or extracted to change the state of a substance without changing its temperature.

Another important feature of PCM cooling compositions is the time needed to ‘recharge’ the composition, i.e., the time needed to freeze the PCM cooling composition. This feature determines, among other things, commercial viability of applications with PCM cooling compositions in, for example, the interior of trailers, trucks or cold storage rooms or the like, since these units can normally not be commercially utilized during the time needed to recharge the composition.

The dynamic thermal efficiency of the cooling element (PCM composition enclosed in heat transfer structures) is also significantly influenced by the thermodynamic properties of the material used to make the heat transfer structures, which may be in the form of tubing, hollow plates or the like, and the ratio surface area of the structure profile to the PCM mass enclosed by said structure profile.

In a typical PCM-based refrigeration system, in the freeze mode refrigerant is run through the structure profile to cool the PCM to a very cold liquid or even a solid. In the defrost mode, the PCM must be heated to temperatures well above the freezing point of water in order to remove frost and ice from the exterior surface of the profile, causing this method to be thermally inefficient, for the added heat must then be removed, increasing the amount of refrigeration that is needed to return the PCM to its desired cooling temperature. This heating and re-cooling of the PCM decreases the durability of the PCM and is not only inefficient, it is time consuming and a costly aspect of the cooling process.

As noted, weight is also a problem with the current beam and plate designs of the PCM containers. This is especially true for the plate form of the container, which is fabricated from heavy gauge carbon steel sheets. Any added weight is detrimental to the economic operation of a refrigerated truck, for it increases fuel cost and reduces payload. Alternatively, if the container is made of a relatively low weight material, that low-weight material has been plastic. While plastic certainly reduces the weight of the apparatus, it is not an effective conductor of heat. Therefore, the trade-off between heat transfer effectiveness and container weight has bene difficult to reconcile. A container that provides effective heat transfer with a density less than steel is preferred.

Therefore, what is needed is an improved heat sink cooling apparatus that enables better cooling functionality than currently exists. What is also needed is an improved heat sink cooling apparatus that minimizes the weight of the apparatus without compromising heat sink cooling functionality. What is also needed is a heat sink cooling apparatus with improved corrosion compatibility. What is also needed is a heat sink cooling apparatus with improved exterior surface-area-to-cooling composition ratio. Further, what is needed is a heat sink cooling apparatus with improved heat exchange profile, improved internal refrigerant tubing profile to maximize heat transfer-to-cooling composition for reduced freezing time and external defrost tubing profile for reduced defrost time. Yet further, what is needed is a heat sink cooling apparatus with improved cooling material composition with high latent heat capacity per volume that minimizes the weight of the apparatus and high durability in terms of freezing/thawing cycles and defrost/freezing cycles.

### SUMMARY OF THE INVENTION

It is an object of the present invention to provide an improved heat sink cooling apparatus that enables better cooling functionality than currently exists. It is also an object to provide an improved heat sink cooling apparatus that minimizes the weight of the apparatus without compromising heat sink cooling functionality. It is further an object to provide a heat sink cooling apparatus with improved corrosion compatibility. Yet further, it is an object of the invention to provide a heat sink cooling apparatus with improved exterior surface-area-to-cooling composition ratio. It is also an object to provide a heat sink cooling apparatus with improved heat exchange profile, improved internal refrigerant tubing profile to maximize heat transfer-to-cooling composition for reduced freezing time and external defrost tubing profile for reduced defrost time. It is another object of the invention to provide a heat sink cooling apparatus with improved cooling material composition with high latent heat capacity per volume that minimizes the weight of the apparatus and high durability in terms of freezing/thawing cycles and defrost/freezing cycles.

These and other objects are achieved with the present invention, which is a heat sink cooling apparatus used to cool an interior volume such as, but not limited to, a truck configured to keep items therein cool. The apparatus includes a container formed of a structural material with high heat exchange properties and decreased weight. The apparatus container is formed of a good structural material with good cooling composition compatibility as well as a good structural material exterior surface area and a good cooling composition volume ratio. The container formed of the good structural material has an external heat exchange profile that maximizes convective heat exchange coefficients. The container is configured with an internal refrigerant tubing profile that maximizes heat transfer to the cooling composition, as well as an external defrost tubing profile maximizing efficiency of the defrost cycle. The present invention also includes a cooling composition with high latent heat capacity per volume and high durability. The combination of the container configuration and the cooling composition produces a highly effective heat sink cooling apparatus. The invention provides a PCM-based heat exchange apparatus including the combination of a unique PCM composition and a unique tubular aluminum profile forming the structure that contains and encloses the PCM composition.

The aluminum profile container with the thickened PCM provides in combination superior cold storage, heat transfer and efficiency of defrost. The PCM with the thickening agent results in increased holdover capacity in a no-leak, safe food grade PCM. The container is a tubular aluminum profile manufactured with a highly conductive aluminum alloy which can be triangular, circular or square with an internal and/or external fin-tube configuration maximizing surface area for heat transfer. The heat sink cooling apparatus is capable of removing heat from (but not limited to) a transport cargo area (truck body) through the processes of conductive and convection heat transfer via the aluminum profile filled with a PCM, either in a passive form of cooling via free convection (hanging mount) or in a forced air plenum chamber.

The PCM composition is a brine solution made of between 10 and 60 percent by weight of one or more water-soluble salts and between 40 and 90 percent by weight of water. The PCM composition further includes one or more thickening agents comprising between 0 and 10 percent by weight of a rheology modifier chosen from a group of thickening aids and crystal inhibiting additives, based on the weight of the brine solution.

The tubular aluminum profile material is chosen from a group of aluminum alloys that are compatible with the specific physical and chemical properties of the brine solution (i.e., the electrolyte in the form of the one or more water-soluble salts). Moreover, the aluminum material chosen to make the container is suitable for conventional manufacturing methods including, but not limited to: a) the ability to extrude it to form the container as desired; b) the difficulty in welding it to provide effective sealing of the container; and c) the corrosiveness of conventional brine-based PCM compositions. Those limitations appear to be reasons that aluminum has not been used in this industry. The tubular aluminum profile of the present invention resolves those concerns. The tubular aluminum profile may include either or both of external and internal configurations of heat transfer enhancing profiles, such as fins, for example, to increase the contact surface area; externally between the surrounding air and the aluminum tubular profile and internally between the PCM composition and the aluminum tubular profile. The optional external surface profile for enhanced heat transfer can be defined by a ratio of external surface area to the mass of the enclosed PCM composition.

The PCM composition of the present invention enclosed in the heat transfer efficient aluminum tubular profiles (cooling elements) of the present invention can absorb large amounts of heat from the environment of the cooling element at a single temperature when the PCM changes from solid to liquid state. The PCM cooling elements of the present invention comprising the PCM compositions with one or more thickening agents that form a semi-rigid colloidal dispersion, and the aluminum tubular profiles can therefore be used to maintain a constant temperature within the interior of a vehicle (truck, trailer, etc.) carrying perishable goods such as fresh food or pharmaceutical and life science products but not limited thereto.

An example embodiment of the aluminum tubular profile is a container body having an interior and an exterior. The PCM is retained in the interior of the container body. In an embodiment of the invention, the container body is triangular in shape. In the example embodiment, a plurality of refrigerant conduits are used to transport refrigerant to and from the container body for PCM freezing and container body defrost purposes. In this embodiment, the apparatus also has one or more optional internal heat transfer elements or fins coupled to the interior surface of the container body wall and arranged to extend into the PCM in the container body to enhance heat exchange with the PCM, in order to optimize PCM chilling. The optional internal heat transfer fins may be employed dependent upon the size of the container body. They may not be necessary for a relatively small container body. This embodiment of the apparatus may also include a plurality of external heat transfer elements or fins coupled to the exterior surface of the container body wall and arranged to extend outwardly therefrom to enhance heat exchange with the environment external to the container body, in order to optimize defrosting of the exterior surface.

The heat exchange cooling apparatus of the present invention provides the combination of a brine-based and thickened colloidal dispersion of the PCM in combination with an aluminum-based tubular profile provides a more efficient arrangement for PCM cooling and heating at lower apparatus weight than has previously been provided. The invention is further defined by the following detailed description, accompanying drawings and appended claims.

### BRIEF DESCRIPTION OF THE DRAWINGS

FIG. 1 is a side view with partial cutaway of an embodiment of the heat sink cooling apparatus of the present invention.

FIG. 2 is a cross sectional end view of the heat sink cooling apparatus of FIG. 1.

FIG. 3 is a cross sectional side view of the heat sink cooling apparatus of FIG. 1.

FIG. 4A is a representation of a test apparatus for evaluating freeze and thaw of a round plastic container containing a PCM. FIG. 4B is a representation of a test apparatus for evaluating freeze and thaw of an Aluminum container containing the same PCM. FIG. 4C is a representation of a test apparatus for evaluating freeze and thaw of a round Aluminum container with fins and containing the same PCM.

FIG. 5 is a chart representing freeze and thaw test results for the containers of FIGS. 4A-4C.

### DETAILED DESCRIPTION OF THE INVENTION

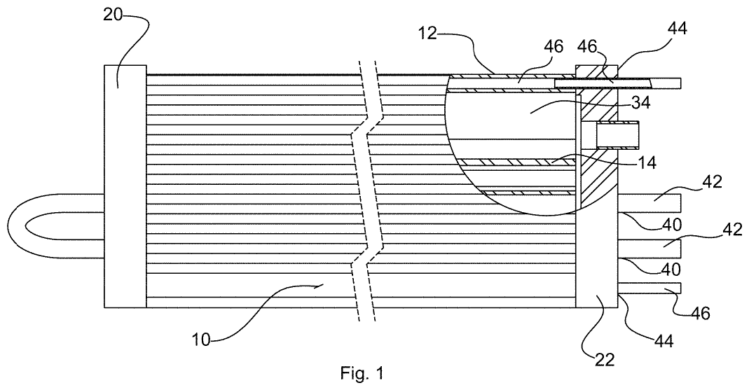

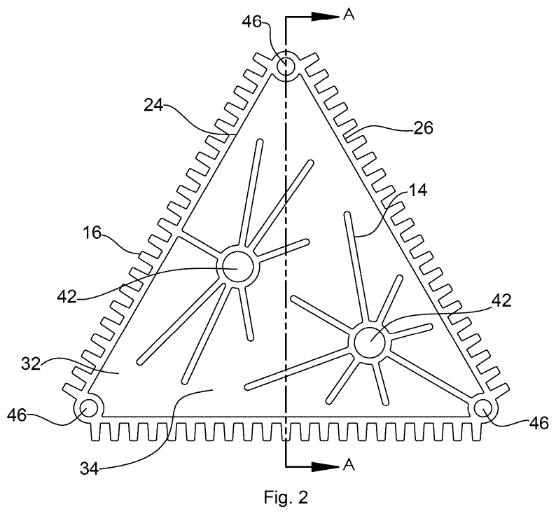

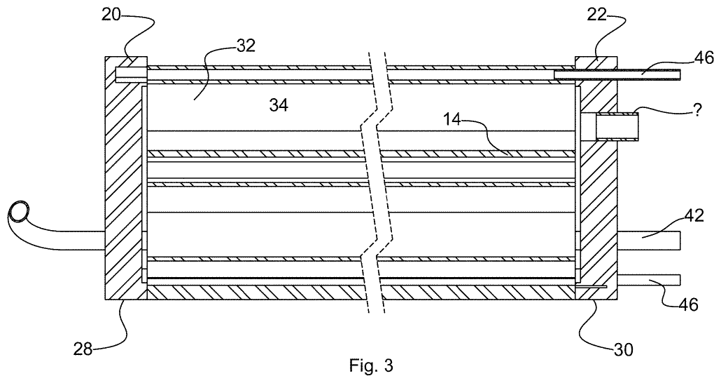

An embodiment of a heat sink cooling apparatus 10 of the present invention is shown in FIGS. 1-3. It is to be understood that this is an example configuration of the apparatus 10 and is not intended to be limiting. The apparatus 10 includes a container body 12, one or more optional internal heat transfer elements 14, one or more optional external heat transfer elements 16, and end cap enclosures 20 and 22. The container body 12 is of a triangular shape and optionally includes internal and external features as described herein to enhance PCM freezing and container body defrosting. The container body 12 as described herein is of a triangular shape; however, it is to be understood that the container body 12 may be of a different shape, such as a polygon form, for example. The container body 12 is single-walled but it may be double-walled.

The end caps 20 and 22 are joined to first end 28 and second end 30 of the container body 12 in a manner that is sufficient to maintain a liquid-tight seal of the container body 12 throughout all operations of the apparatus 10 when used to cool an interior volume over a commercially reasonable life expectancy. For example, the end caps 20 and 22 are permanently or removable joined to ends 28 and 30 of the container body 12. The container body 12 with the end caps 20 and 22 joined thereto is arranged to contain therein a PCM 34.

The one or more optional internal heat transfer elements 14 are joined to, and extend from, internal wall 24 of the container body 12 into the PCM 34. The number of internal heat transfer elements 14, the extent to which they extend into the PCM 34, and their placement in the PCM 34 is selectable as a function of the desired rate at which the PCM 34 is to be cooled or heated.

The one or more optional external heat transfer elements 16 are joined to, and extend from, external wall 26 of the container body 12 to the environment surrounding the container body 12. The number of external heat transfer elements 16, the extent to which they extend outward to the surrounding environment, and their positioning on the external wall 26 is selectable as a function of the desired rate at which cooling occurs. The internal heat transfer elements 14 and the external heat transfer elements 16, which are shown in the figures as fins but which may be of other shapes and configurations, extend the heat transfer surfaces associated with PCM cooling and heating. This added surface area improves the rate at which heat is absorbed from the surrounding environment by the PCM 34.

The end caps 20 and 22 are configured to contain the refrigerant charge within the container body 12. The end caps 20 and 22 include one or more PCM heat transfer ports 40 through which PCM heat transfer conduits 42 pass into and through the interior of the container body 12. The conduits 42 provide the means by which liquid or hot refrigerant gas exchanges heat with the PCM to freeze the PCM 34. The PCM heat transfer conduits 42 may be coupled to the internal heat transfer elements 14 to enhance heat transfer with the PCM 34. The end caps 20 and 22 further include one or more container defrost ports 44 through which defrost transfer conduits 46 pass along the outer perimeter of the interior of the container body 12. The defrost transfer conduits 46 may form an integral part of the container body perimeter as shown, or they may be interior or exterior to the container body 12. The defrost transfer conduits 46 provide the means by which liquid or hot refrigerant gas exchanges heat with the container body 12 to minimize frost on the external wall 26 thereof. The end caps 20 and 22 cover the entire ends 28 and 30 of the container body 12. The end caps 20 and 22 may be permanently or removably joined to the ends 28 and 30 by press fit, bonding or brazing.

The components of the apparatus 10 are made of extruded aluminum, which makes the apparatus 10 a relatively lightweight design. In particular, using the ratio:

(total thermal energy absorbed)/(total weight)

as a measure, a weight reduction of 40% or more can be realized with the triangular-shaped container body 12 configuration, decreasing significantly vehicle fuel cost and increasing significantly payload capacity. It has been determined that in order to fabricate the apparatus 10 in the configuration described, the aluminum must be manufacturable in a way that may be extruded in a cost effective process and that minimizes the chance of leakage of the PCM 34 out of the apparatus 10 by being reasonably weldable. In particular, any one or more of aluminum alloys 6060, 6061, 6063, 3003, 3103 and 3105 have been found to be suitable for that purpose. Other alloys may also have the same manufacturing characteristics and so may be used to make the apparatus 10. The apparatus 10 made as described herein is particularly effective as a tubular heat sink apparatus when the ratio tube perimeter (TP) to tube cavity cross section area (TCC) is equal to or greater than 1.5 inch/square inch.

The PCM 34 of the present invention used in the apparatus 10 made of aluminum is composed of a combination of materials that provide a desired heating and cooling profile while also limiting the corrosiveness of that composition on the aluminum container. PCM 34 of the present invention, which may be used in non-aluminum containers as well, is a combination of a brine solution and a thickening agent. The brine solution provides the latent heat required for desired heating and cooling. The thickening agent makes the PCM 34 a semi-solid, including when warm, that reduces the sedimentation and resultant concentration of the one or more mineral salts at the surface of the aluminum apparatus 10, thereby reducing corrosive effect on that material. A reduction of corrosive effect improves the chance of maintaining the seal of the apparatus 10. The thickening agent also limits the impact of a leak in that the semi-solid material is less likely to spread widely within the truck, etc., where the apparatus 10 resides.

The brine solution includes a combination of one or more water-soluble mineral salts and water. The one or more mineral salts may be chosen from NaNO_{3 and} KC1 but not limited thereto. The one or more water-soluble mineral salts comprise between about 10 and about 60 percent by weight of the PCM 34. The water comprises between about 40 and about 90 percent by weight of the PCM 34. The thickening agent includes one or more of guar gum and carboxymethyl cellulose. The thickening agent comprises about 0.5 to about 10 percent by weight of the PCM 34.

The effectiveness of the combination of the apparatus 10 as an aluminum tubular construct with a triangular profile as shown in the drawings, and the PCM 34 with thickening agent as described herein, was evaluated in a test.

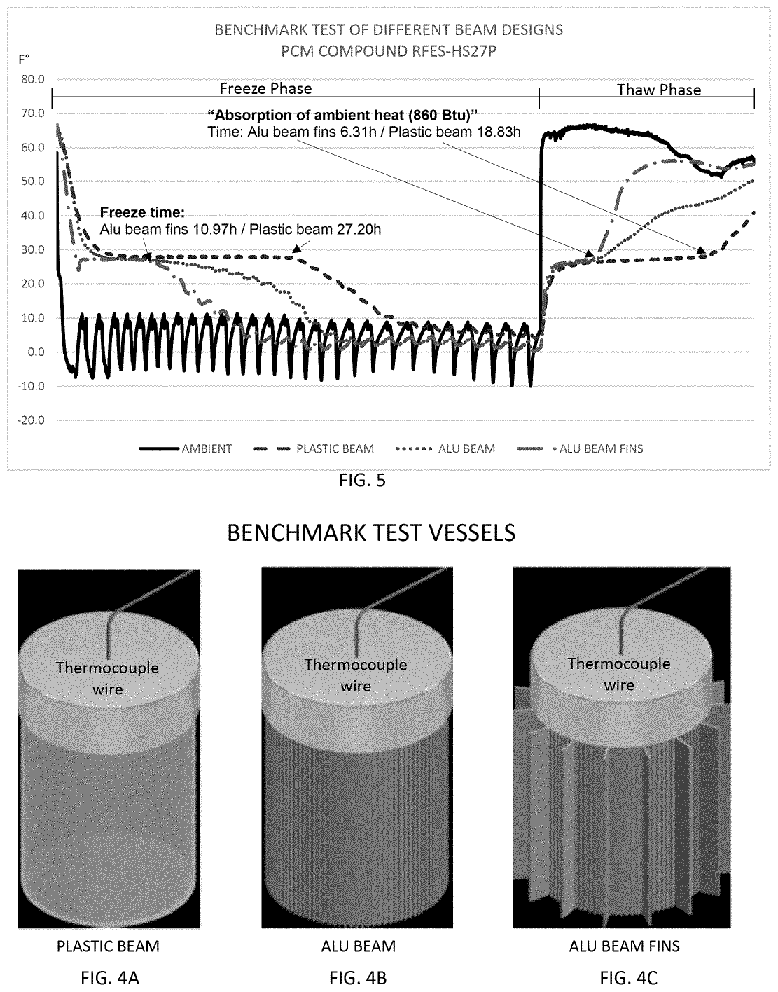

Three test specimens were produced. The test specimens were: A) a conventional container with circular profile made of a nonmetallic material such as a viscoelastic material such as a plastic including but not limited to polypropylene represented in FIG. 4A; B) a conventional container with circular profile made of aluminum represented in FIG. 4B; and C) a conventional container with circular profile including internal and external fins such as elements 14 and 16, made of aluminum represented in FIG. 4C. The same PCM was used in all containers. The test specimens all contained a similar amount and identical grade of PCM (3.000 kg, 6.614 lb) enclosed in the profile. That PCM comprised for all specimens a compound identified as RFES-HS27P, which has a composition of water, 88.3 percent by weight of the PCM, potassium nitrate (KNO₃), 11.7 percent by weight of the PCM and the thickening agent, which includes guar gum, 3.0 percent by weight of the PCM, and carboxymethyl cellulose, 3.5 percent by weight of the PCM.

Each test specimen underwent a freeze and thaw trajectory testing simultaneously. The test specimens were placed in a freezer and remained in the freezer until the internal temperature of all specimens were close to the external temperature (outside the specimens) in the freezer. The test specimens were then removed from the freezer and subjected to room temperature. The thaw phase of the test was complete when the internal temperature of all test specimens had converged with the ambient (room) temperature. The internal temperatures of the test specimens (center of the PCM enclosed in the profile) and the ambient (AMB) temperature (outside the specimens) were recorded during the entire freeze/thaw trajectory. The test results are shown in FIG. 5.

The test results indicate that an aluminum container equipped with internal and external fins significantly exceeds the over-all performance of a conventional plastic container, in both the thaw phase and the freeze phase. The aluminum container with fins absorbed 198% more heat per time unit compared to an equivalent conventional plastic container. This performance advantage is of significant importance when cargo is subjected to sudden heat loads (door openings) whereby a heat sink design with aluminum container, including fins, will rapidly regain the set cooling temperature and accordingly maintain appropriate cold chain management performance. The freeze (charge) time for an aluminum container with fins is 60% shorter than the freeze time for an equivalent conventional plastic container. The shorter freeze (charge) time results in valuable additional “up-time” for a refrigeration vehicle.

While the present invention has been described with reference to a specific example of the configuration of the apparatus and its related components, it is to be understood that the invention is a broader concept defined by the following claims and reasonable equivalents directed to the use of a PCM material with thickening agent and an aluminum-based container for that PCM material.

What is claimed is:

1. A heat sink cooling apparatus comprising:
a container body having an interior and an exterior, the container body formed of a structural material; and
a Phase Change Material (PCM) contained in the container body within the interior of the container body, wherein the PCM includes a combination of a brine solution and a thickening agent, and wherein the structural material of the container body and the PCM are corrosion compatible.

2. The apparatus of claim 1 wherein the container body is formed of Aluminum.

3. The apparatus of claim 2 wherein the Aluminum is selected from one or more of the group of Aluminum alloys comprising alloys 6060, 6061, 6063, 3003, 3103 and 3105.

4. The apparatus of claim 1 wherein the brine solution includes one or more water-soluble mineral salts.

5. The apparatus of claim 4 wherein the brine solution includes the one or more water-soluble mineral salts comprising between about 10 percent by weight and about 60 percent by weight of the PCM and water comprising between about 40 percent by weight and about 90 percent by weight of the PCM.

6. The apparatus of claim 5 wherein the thickening agent is chosen from guar gum and carboxymethyl cellulose.

7. The apparatus of claim 6 wherein the thickening agent comprises between about 0.5 percent and about 10 percent by weight of the PCM.

8. The apparatus of claim 1 wherein the container body is of a triangular shape.

9. The apparatus of claim 1 further comprising one or more external heat transfer elements coupled to the exterior of the container body and arranged to extend into an environment surrounding the container body.

10. The apparatus of claim 1 further comprising one or more internal heat transfer elements coupled to the interior of the container body and arranged to extend into the PCM in the container body.

11. The apparatus of claim 1 wherein a ratio of tube perimeter (TP) to tube cavity cross section area (TCC) is equal to or greater than 1.5 inch/square inch.

12. A heat transfer Phase Change Material (PCM) composition for cooling an object, the composition comprising:
a brine solution; and
a thickening agent.

13. The PCM composition of claim 12 wherein the brine solution includes one or more water-soluble mineral salts.

14. The PCM composition of claim 13 wherein the brine solution includes the one or more water-soluble mineral salts comprising between about 10 percent by weight and about 60 percent by weight of the PCM and water comprising between about 40 percent by weight and about 90 percent by weight of the PCM.

15. The PCM composition of claim 14 wherein the thickening agent is chosen from guar gum and carboxymethyl cellulose.

16. The PCM composition of claim 15 wherein the thickening agent comprises between about 0.5 percent and about 10 percent by weight of the PCM.
